(19) United States
(12) Patent Application Publication
(10) Pub. No.: US 2009/0147203 A1
(43) Pub. Date: Jun. 11, 2009

(54) ACTIVE MATRIX TYPE LIQUID CRYSTAL DISPLAY HAVING ALUMINUM AND SILVER METAL LAYERS

(75) Inventor: Yoshinori TOMIHARI, Tokyo (JP)

Correspondence Address: YOUNG & THOMPSON, 209 Madison Street, Suite 500, ALEXANDRIA, VA, 22314, US

(73) Assignee: NEC CORPORATION, TOKYO (JP)

(21) Appl. No.: 12/366,135

(22) Filed: Feb. 5, 2009

Related U.S. Application Data
(62) Division of application No. 11/054,562, filed on Feb. 10, 2005.

(30) Foreign Application Priority Data
Feb. 10, 2004 (JP) 2004-034287

(51) Int. Cl. G02F 1/1343; H01L 21/77

(52) U.S. Cl. 349/147; 438/30; 257/E21.598

(57) ABSTRACT

A first metal layer of aluminum or an aluminum alloy is formed on a second interlayer insulating layer, and a second metal layer of silver or a silver alloy, which is patterned in the same pattern as the first metal layer, is formed on the first metal layer. The first metal layer and the second metal layer constitute wirings. The wirings are patterned in such a way as to overlie the gate lines and data lines of associated TFTs, and are laid out in such a way as to cover the TFTs.

### BACKGROUND OF THE INVENTION

1. Field of the Invention

The present invention relates to an active matrix type liquid crystal display including a thin film transistor (TFT) array substrate (TFT array substrate) having a plurality of thin film transistors (TFTs) arranged in a matrix form, or an MOS (Metal Oxide Semiconductor) transistor array substrate (MOS array substrate) having a matrix of MOS transistors, and a manufacture method for the active matrix type liquid crystal display. More particularly, the present invention relates to an active matrix type liquid crystal display suitable for use as a light bulb for a projection type display apparatus, and a manufacture method thereof.

2. Description of the Related Art

Recently, various display apparatuses using liquid crystal displays have been developed as a wall hanging TV set, a projection type TV set, a display apparatus for an OA apparatus, and the like. Particularly, an active matrix type liquid crystal display which uses active elements as switching elements is effective in realizing a display apparatus for a high-quality OA apparatus and a high-definition TV set for its advantages such that the contrast and the response speed do not drop even when the number of scan lines is increased. The active matrix type liquid crystal display, if used as a light bulb for a projection type display apparatus called a projector, can easily provide a large screen display.

Normally, high-luminance light from a light source is input to a liquid crystal display for a light bulb. As an active element corresponding to each pixel of a liquid crystal layer is driven, a voltage corresponding to image information is applied to each pixel to control the transmittance of light at each pixel. When light emitted from the light source passes through the liquid crystal layer, therefore, the intensity of the transmitted light is adjusted pixel by pixel and an image is added to the transmitted light. The light having passed the liquid crystal display is magnified by a projection optical system comprising lenses or so and is displayed on an external screen. Liquid crystal displays for a light bulb include a transmission type liquid crystal display which passes light from a light source and projects an image onto a screen, and a reflection type liquid crystal display which reflects light from a light source and projects an image onto a screen.

In general, an array substrate to be used in a transmission type liquid crystal display comprises TFTs laid out in a matrix form on a transparent substrate, gate lines extending in the row direction of the matrix of TFTs, data lines extending in the column direction of the matrix of TFTs and connected to the source regions of the TFTs, pixel electrodes, and wirings which connect the drain regions of the TFTs to the associated pixel electrodes and serve as a light-shielding layer. An array substrate to be used in a reflection type liquid crystal display comprises MOS transistors laid out in a matrix form on a semiconductor substrate, gate lines extending in the row direction of the matrix of MOS transistors, data lines extending in the column direction of the matrix of MOS transistors and connected to the source regions of the MOS transistors, and reflection pixel electrodes electrically connected to the drain regions of the MOS transistors.

The following will give a detailed description of an active matrix type liquid crystal display using the conventional TFT array substrate. FIG. 1 is a plan view showing the TFT array substrate of the conventional active matrix type liquid crystal display. FIG. 2 is a cross-sectional view showing the conventional active matrix type liquid crystal display along line A-A in FIG. 1.

As shown in FIGS. 1 and 2, the conventional active matrix type liquid crystal display is provided with a TFT array substrate and an opposing substrate facing each other, with a liquid crystal layer provided between both substrates. The TFT array substrate is provided with a transparent substrate 1. A plurality of polycrystalline silicon layers 3 patterned in an approximately L shape are formed on the transparent substrate 1 in a matrix form via a silicon oxide (SiO₂) layer 2. The polycrystalline silicon layers 3 serve as active layers of the TFTs. Specifically, each of the polycrystalline silicon layers 3 includes a non-doped channel region 3b, a source region 3a doped with an impurity at a high concentration, and a drain region 3c doped with an impurity at a high concentration. The source region 3a and the drain region 3c are formed with the channel region 3b in between. The polycrystalline silicon layers 3 are covered with a gate insulating layer 4 formed on the silicon oxide layer 2

A plurality of gate lines 5 each formed by an impurity-doped polycrystalline silicon layer, a metal silicide layer or so are formed on the gate insulating layer 4. The gate lines 5 extend in parallel to one another and in the row direction of TFTs laid out in a matrix form. The gate lines 5 are laid out in such a way as to overlie the channel regions 3b of the matrix of TFTs, and serve as the gate electrodes of the TFTs. The gate lines 5 are covered with a first interlayer insulating layer 6 formed on the gate insulating layer 4. A plurality of data lines 7 each formed by an aluminum layer are formed on the first interlayer insulating layer 6. The data lines 7 extend in parallel to one another and in the column direction of the matrix of TFTs, and are laid out in such a way as to overlie the polycrystalline silicon layers 3 laid out in a matrix form. The data lines 7 are electrically connected to the source regions 3a of the matrix of TFTs via first contact holes 17 which penetrate the first interlayer insulating layer 6 and the gate insulating layer 4. The data lines 7 are covered with a second interlayer insulating layer 8 formed on the first interlayer insulating layer 6.

Wirings 9 formed by an aluminum or aluminum alloy layer or so are formed on the second interlayer insulating layer 8. The wirings 9 are electrically connected to the drain regions 3c of the associated TFTs via second contact holes 18 which penetrate the second interlayer insulating layer 8, the first interlayer insulating layer 6 and the gate insulating layer 4. The wirings 9 are patterned and laid out in such a way as to overlie the associated gate lines 5 and the associated data lines 7, and also serve as a light-shielding layer. Barrier metals 20 of titanium or so are formed on partial regions of the wirings 9. A third interlayer insulating layer 10 is provided in such a way as to cover the wirings 9 and the barrier metals 20, and a third contact hole 19 which penetrates the third interlayer insulating layer 10 is formed in that region of the third interlayer insulating layer 10 which directly overlies the barrier metal 20.

A plurality of pixel electrodes 11 each having an approximately rectangular shape and formed by ITO (Indium Tin Oxide) or so are formed on the third interlayer insulating layer 10. The pixel electrodes 11 are respectively laid out at a plurality of pixel regions each surrounded by the associated gate line 5 and the associated data line 7. Each pixel electrode 11 is electrically connected to the drain region 3c of the associated TFT via the associated third contact hole 19, the associated barrier metal 20 and the associated wiring 9. The barrier metal 20 serves to prevent electric corrosion from occurring due to direct contact of the wiring 9 of aluminum or an aluminum alloy with the pixel electrode 11 of ITO, thereby preventing the deterioration of the contact resistance by the time elapse. An alignment layer 12, which has undergone a predetermined alignment process, is formed on the pixel electrodes 11.

An opposing electrode 14 is formed on the entire surface of an opposing substrate 13, and an alignment layer 15, which has undergone a predetermined alignment process, is formed under the opposing electrode 14. A liquid crystal is sealed between the TFT array substrate and the opposing substrate 13 formed in the above-described manner, thereby forming a liquid crystal layer 16.

In the transmission type liquid crystal display equipped with the conventional TFT array substrate having the above-described structure, light is input from the surface side of the opposing substrate. The intensity of the light input to the pixel regions is adjusted by the liquid crystal layer 16, and the light then transmits the liquid crystal display.

The light that is input to non-transmittive regions formed by the TFTs, the gate lines 5 and the data lines 7 is mostly reflected by the wirings 9 formed closer to the light incident side than the TFTs, while the other part of the light is absorbed and converted to heat which raises the temperature of the panel. In addition, the recent attempts of downsizing projection display apparatuses compact and improving the luminance are increasing the intensity of light to be input to the liquid crystal displays. This apparently leads to a greater rise in panel temperature which would be caused by absorption of light, thus quickening the degradation of the liquid crystal displays.

Various improvements have been made to avoid such a problem. For example, Japanese Patent Laid-Open Publication No. H7-43700 discloses a scheme of preventing the temperature of the liquid crystal in a liquid crystal display from rising by reflecting incident light, which is not used in displaying an image, at a reflection layer of gold, sliver, aluminum or so. Japanese Patent Laid-Open Publication No. H11-218751 discloses the use of silver or a silver alloy with a high reflectance for the reflection electrode of a reflection type liquid crystal display to thereby improve the efficiency of light usage and prevention of heat generation caused by light absorption. Japanese Patent Laid-Open Publication No. 2003-131013 discloses the use of silver for a light-shielding member to improve the light reflectance, thereby suppressing a rise in the temperature of the liquid crystal panel or so.

As the conventional measure against the occurrence of electric corrosion caused by direction contact of the wirings 9 of aluminum or an aluminum alloy with ITO of the pixel electrodes 11 of ITO, the barrier metal 20 is used as mentioned earlier, but this measure leads to an increase in the number of processing steps and a cost increase. Japanese Patent Laid-Open Publication No. 2002-91338 discloses, as another solution, the use of silver or a silver alloy as the material for the wirings which does not cause electric corrosion with ITO, thereby eliminating the need for the barrier metal. Japanese Patent Laid-Open Publication No. 2002-151434 discloses the problem of electric corrosion being overcome by forming wirings for display elements with a silver alloy containing a low melting point metal.

Those prior arts however have the following problems. Although the above-noted publications disclose the techniques of improving the light reflectance by using silver or a silver alloy to restrain a temperature rise of the liquid crystal panel or so, preventing electric corrosion of the wirings with the pixel electrodes, silver is more expensive than aluminum and an aluminum alloy which are the conventional materials for the wirings. In addition, silver is not popular as one of the materials for a semiconductor device, and the effect of cost reduction through mass production cannot be expected.

### SUMMARY OF THE INVENTION

Accordingly, it is an object of the present invention to provide an active matrix type liquid crystal display which can achieve a light reflectance performance and an electric corrosion preventing effect equivalent to those obtained by the use of silver alone for the wiring material and the light-shielding layer or the like, at a lower cost than is achieved when silver alone is used, and a manufacture method for the liquid crystal display.

An active matrix type liquid crystal display according to the first aspect of the present invention comprises an array substrate, an opposing substrate arranged opposite to the array substrate, and a liquid crystal layer provided between the array substrate and the opposing substrate. The array substrate has a substrate, a plurality of transistors laid out on the substrate in a matrix form, gate lines extending along a row direction of that matrix, data lines extending along a column direction of the matrix and connected to one of source regions and drain regions of the transistors, pixel electrodes arranged at pixel regions on the substrate, and wirings for respectively connecting the other one of the source regions and the drain regions of the transistors to the pixel electrodes. Each wiring has a first metal layer of aluminum or an aluminum alloy and a second metal layer of silver or a silver alloy laminated on a light-incident side surface of the first metal layer.

It is preferable that each of the gate lines should have a first metal layer of aluminum or an aluminum alloy, and a second metal layer of silver or a silver alloy laminated on a light-incident side surface of the first metal layer. Further, it is preferable that each of the data lines should have a first metal layer of aluminum or an aluminum alloy, and a second metal layer of silver or a silver alloy laminated on a light-incident side surface of the first metal layer.

An active matrix type liquid crystal display according to the second aspect of the present invention comprises an array substrate, an opposing substrate arranged opposite to the array substrate, and a liquid crystal layer provided between the array substrate and the opposing substrate. The array substrate has a substrate, a plurality of transistors laid out on the substrate in a matrix form, gate lines extending along a row direction of that matrix, data lines extending along a column direction of the matrix and connected to one of source regions and drain regions of the transistors, pixel electrodes arranged at pixel regions on the substrate, wirings for respectively connecting the other one of the source regions and the drain regions of the transistors to the pixel electrodes, and a barrier metal intervening between each of the pixel electrodes and an associated one of the wirings. Each gate line has a first metal layer of aluminum or an aluminum alloy and a second metal layer of silver or a silver alloy laminated on a light-incident side surface of the first metal layer.

An active matrix type liquid crystal display according to the third aspect of the present invention comprises an array substrate, an opposing substrate arranged opposite to the array substrate, and a liquid crystal layer provided between the array substrate and the opposing substrate. The array substrate has a substrate, a plurality of transistors laid out on the substrate in a matrix form, gate lines extending along a row direction of that matrix, data lines extending along a column direction of the matrix and connected to one of source regions and drain regions of the transistors, pixel electrodes arranged at pixel regions on the substrate, wirings for respectively connecting the other one of the source regions and the drain regions of the transistors to the pixel electrodes, and a barrier metal intervening between each of the pixel electrodes and an associated one of the wirings. Each data line has a first metal layer of aluminum or an aluminum alloy and a second metal layer of silver or a silver alloy laminated on a light-incident side surface of the first metal layer.

An active matrix type liquid crystal display according to the fourth aspect of the present invention comprises an array substrate, an opposing substrate arranged opposite to the array substrate, and a liquid crystal layer provided between the array substrate and the opposing substrate. The array substrate has a substrate, a plurality of transistors laid out on the substrate in a matrix form, gate lines extending along a row direction of that matrix, data lines extending along a column direction of the matrix and connected to one of source regions and drain regions of the transistors, pixel electrodes arranged at pixel regions on the substrate, and wirings for respectively connecting the other one of the source regions and the drain regions of the transistors to the pixel electrodes. The opposing substrate has a substrate, and an opposing light-shielding layer laid out at a region including a region directly overlying at least one of the gate lines and the data lines on the substrate. The opposing light-shielding layer has a first metal layer of aluminum or an aluminum alloy and a second metal layer of silver or a silver alloy laminated on a light-incident side surface of the first metal layer.

It is preferable that each of at least one of the wirings, the gate lines and the data lines should have a first metal layer of aluminum or an aluminum alloy, and a second metal layer of silver or a silver alloy laminated on a light-incident side surface of the first metal layer.

An active matrix type liquid crystal display according to the fifth aspect of the present invention comprises an array substrate, an opposing substrate arranged opposite to the array substrate, and a liquid crystal layer provided between the array substrate and the opposing substrate. The array substrate has a semiconductor substrate, a plurality of transistors laid out at a top surface of the semiconductor substrate in a matrix form, gate lines extending along a row direction of that matrix, data lines extending along a column direction of the matrix and connected to one of source regions and drain regions of the transistors, and reflection pixel electrodes which reflect light and are connected to the other one of the source regions and the drain regions of the transistors. Each reflection pixel electrode has a first metal layer of aluminum or an aluminum alloy and a second metal layer of silver or a silver alloy laminated on a light-incident side surface of the first metal layer.

A manufacture method for an active matrix type liquid crystal display according to the sixth aspect of the present invention comprises the steps of forming an array substrate, forming an opposing substrate, and forming a liquid crystal layer between the array substrate and the opposing substrate, after arranging the array substrate and the opposing substrate opposite to each other. The forming of the array substrate includes the steps of forming a plurality of transistors on the substrate in a matrix form, forming gate lines in such a way as to extend along a row direction of that matrix, forming data lines in such a way as to extend along a column direction of the matrix and connected to one of source regions and drain regions of the transistors, forming wirings in such a way that the wirings are respectively connected to the other one of the source regions and the drain regions of the transistors, and forming pixel electrodes at pixel regions on the substrate in such a way as to be connected to the wirings. The forming of the wiring includes forming a first metal layer of aluminum or an aluminum alloy, forming a second metal layer of silver or a silver alloy laminated on a light-incident side surface of the first metal layer, and patterning the first metal layer and the second metal layer by etching the first metal layer and the second metal layer using a same resist pattern.

A manufacture method for an active matrix type liquid crystal display according to the seventh aspect of the present invention comprises the steps of forming an array substrate, forming an opposing substrate, and forming a liquid crystal layer between the array substrate and the opposing substrate, after arranging the array substrate and the opposing substrate opposite to each other. The forming of the array substrate includes the steps of forming a plurality of transistors on the substrate in a matrix form, forming gate lines in such a way as to extend along a row direction of that matrix, forming data lines in such a way as to extend along a column direction of the matrix and connected to one of source regions and drain regions of the transistors, forming wirings in such a way that the wirings are respectively connected to the other one of the source regions and the drain regions of the transistors, forming a barrier metal on a part of the wirings, and forming pixel electrodes at pixel regions on the substrate in such a way as to be connected to the wirings via the barrier metal. The forming of the opposing substrate has the step of forming an opposing light-shielding layer at a region including a region directly overlying at least one of the gate lines and the data lines on the substrate. The forming of the opposing light-shielding layer includes forming a first metal layer of aluminum or an aluminum alloy, forming a second metal layer of silver or a silver alloy laminated on a light-incident side surface of the first metal layer, and patterning the first metal layer and the second metal layer by etching the first metal layer and the second metal layer using a same resist pattern.

A manufacture method for an active matrix type liquid crystal display according to the eighth aspect of the present invention comprises the steps of forming an array substrate, forming an opposing substrate, and forming a liquid crystal layer between the array substrate and the opposing substrate, after arranging the array substrate and the opposing substrate opposite to each other. The forming of the array substrate includes the steps of forming a plurality of transistors on a semiconductor substrate in a matrix form, forming gate lines in such a way as to extend along a row direction of that matrix, forming data lines in such a way as to extend along a column direction of the matrix and connected to one of source regions and drain regions of the transistors, and forming reflection pixel electrodes, which reflect light, in such a way that the reflection pixel electrodes are respectively connected to the other one of the source regions and the drain regions of the transistors. The forming of the reflection pixel electrode includes forming a first metal layer of aluminum or an aluminum alloy, forming a second metal layer of silver or a silver alloy laminated on a light-incident side surface of the first metal layer, and patterning the first metal layer and the second metal layer by etching the first metal layer and the second metal layer using a same resist pattern.

As the wiring in the active matrix type liquid crystal display according to the first aspect of the present invention is formed by the lamination of a first metal layer of aluminum or an aluminum alloy and a second metal layer of silver or a silver alloy arranged on the first metal layer on the light-incident side, the light reflection performance equivalent to the one when wirings are formed of silver alone, and an effect of restraining a rise in panel temperature, which is equivalent to the effect obtained when the wirings are formed of silver alone, can be achieved at a lower cost than is done when silver alone is used. Because of the use of silver or a silver alloy for the second metal layer of the wirings, inadequate contact, which would occur between aluminum or an aluminum alloy and ITO of the pixel electrodes, and aging-originated deterioration can be prevented in the same way as done when the wirings are formed of silver alone, and the active matrix type liquid crystal display can be realized at a low cost. If at least one of each gate line and each data line is formed by the lamination of a first metal layer of aluminum or an aluminum alloy and a second metal layer of silver or a silver alloy on the first metal layer on the light-incident side, the effect of restraining a rise in panel temperature can be enhanced more.

As the gate line in the active matrix type liquid crystal display according to the second aspect of the present invention is formed by the lamination of a first metal layer of aluminum or an aluminum alloy and a second metal layer of silver or a silver alloy arranged on the first metal layer on the light-incident side, an advantage equivalent to the advantage of the first aspect of the present invention can be acquired. Further, the intervention of the barrier metal between the pixel electrodes and the wirings can prevent electric corrosion of the wirings.

As the data line in the active matrix type liquid crystal display according to the third aspect of the present invention is formed by the lamination of a first metal layer of aluminum or an aluminum alloy and a second metal layer of silver or a silver alloy arranged on the first metal layer on the light-incident side, an advantage equivalent to the advantage of the first aspect of the present invention can be acquired. Further, the intervention of the barrier metal between the pixel electrodes and the wirings can prevent electric corrosion of the wirings.

As the opposing light-shielding layer in the active matrix type liquid crystal display according to the fourth aspect of the present invention is formed by the lamination of a first metal layer of aluminum or an aluminum alloy and a second metal layer of silver or a silver alloy arranged on the first metal layer on the light-incident side, an advantage equivalent to the advantage of the first aspect of the present invention can be acquired.

As the reflection pixel electrode in the active matrix type liquid crystal display according to the fifth aspect of the present invention is formed by the lamination of a first metal layer of aluminum or an aluminum alloy and a second metal layer of silver or a silver alloy arranged on the first metal layer on the light-incident side, a light reflectance performance equivalent to the one obtained when the reflection pixel electrode is formed of silver alone, and an effect of restraining a rise in panel temperature, which is equivalent to the effect obtained when the reflection pixel electrode is formed of silver alone, can be achieved at a lower cost than is done by the use of silver alone.

### BRIEF DESCRIPTION OF THE DRAWINGS

FIG. 1 is a plan view showing the TFT array substrate of a conventional active matrix type liquid crystal display;

FIG. 2 is a cross-sectional view showing the conventional active matrix type liquid crystal display along line A-A in FIG. 1;

FIG. 3 is a cross-sectional view showing a liquid crystal display according to a first embodiment of the present invention;

FIG. 4 is a cross-sectional view showing a liquid crystal display according to a second embodiment of the present invention;

FIG. 5 is a cross-sectional view showing a liquid crystal display according to a third embodiment of the present invention;

FIG. 6 is a cross-sectional view showing a liquid crystal display according to a fourth embodiment of the present invention;

FIG. 7 is a cross-sectional view showing a liquid crystal display according to a fifth embodiment of the present invention;

FIG. 8 is a cross-sectional view showing a liquid crystal display according to a sixth embodiment of the present invention; and

FIG. 9 is a cross-sectional view showing a liquid crystal display according to a seventh embodiment of the present invention.

### DETAILED DESCRIPTION OF THE PREFERRED EMBODIMENTS

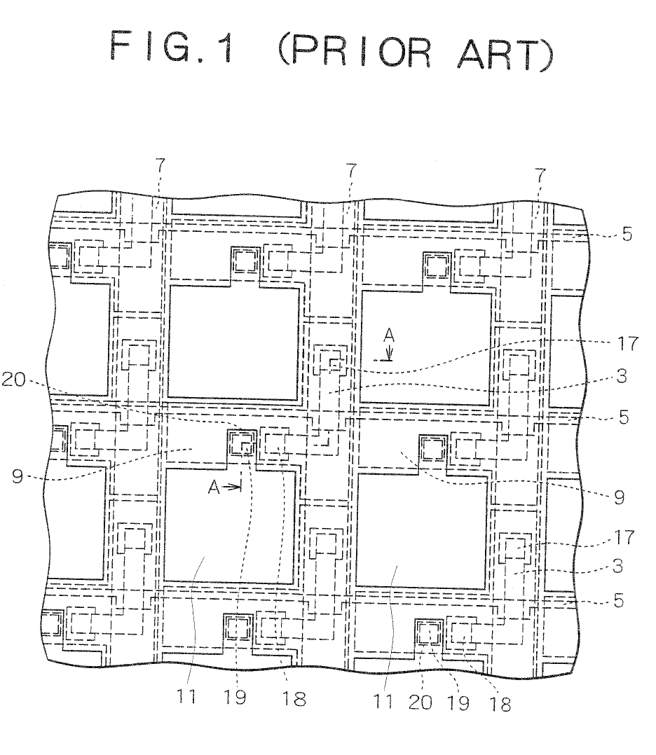

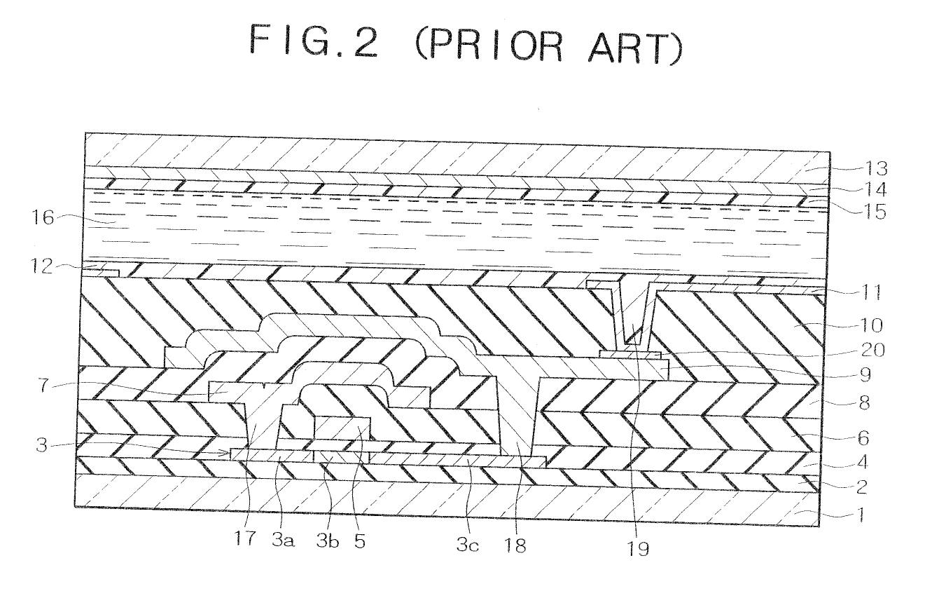

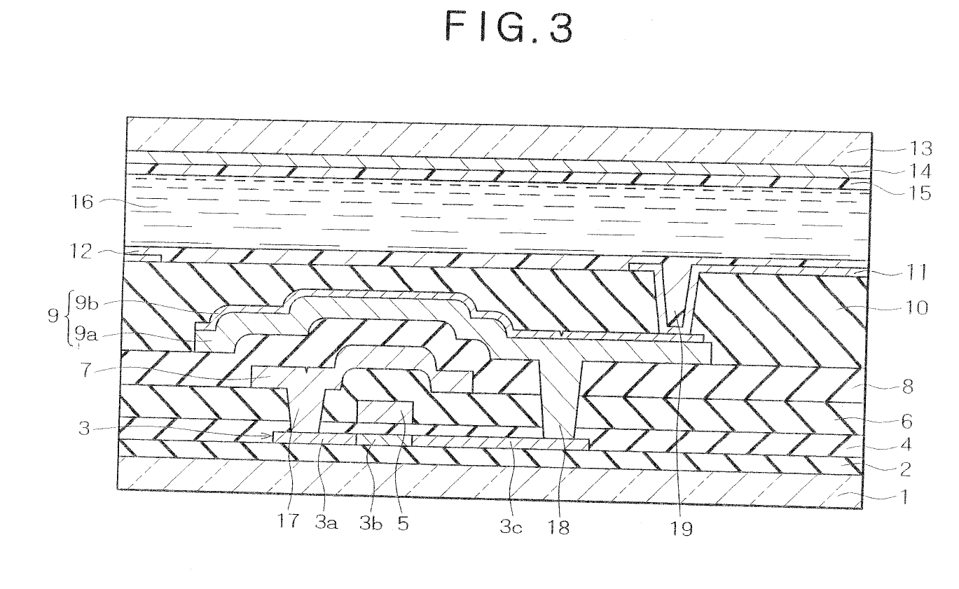

Preferred embodiments of the present invention will specifically be described below with reference to the accompanying drawings. FIG. 3 is a cross-sectional view showing a liquid crystal display according to the first embodiment of the present invention. The position of the cross section in FIG. 3 is equivalent to the position along line A-A in FIG. 1 showing the prior art. Same reference symbols are given to those components in FIG. 3 which are the same as the corresponding components in FIG. 2.

As shown in FIG. 3, the liquid crystal display according to the embodiment includes a TFT array substrate, an opposing substrate arranged at a position facing the TFT array substrate, and a liquid crystal layer provided between the TFT array substrate and the opposing substrate. The TFT array substrate is provided with a substrate 1. The substrate 1 is formed of a transparent and insulative material, such as glass. A silicon oxide (SiO₂) layer 2 is formed on the entire top surface of the substrate 1. The silicon oxide layer 2 serves to prevent diffusion of a heavy metal contained in the substrate 1. Multiple polycrystalline silicon layers 3 patterned in an approximately L shape are formed on the silicon oxide layer 2. The polycrystalline silicon layers 3 are laid out at intersections of gate lines 5 and data lines 7, both of which will be discussed later. Each of the polycrystalline silicon layers 3 serves as an active layer of the associated TFT. Specifically, each of the polycrystalline silicon layers 3 includes a non-doped channel region 3b, a source region 3a doped with an impurity at a high concentration, and a drain region 3c doped with an impurity at a high concentration. The source region 3a and the drain region 3c are formed with the channel region 3b in between. The polycrystalline silicon layers 3 are covered with a gate insulating layer 4 formed on the silicon oxide layer 2.

A plurality of gate lines 5 each formed by an impurity-doped polycrystalline silicon layer, a silicide layer or so are formed on the gate insulating layer 4. The gate lines 5 extend in parallel to one another and in the row direction of TFTs laid out in a matrix form. The gate lines 5 are laid out in such a way as to overlie the channel regions 3b of the TFTs arranged in a matrix form as seen from a direction perpendicular to the top surface of the substrate 1 (hereinafter called “as seen from a planar view”), and serve as the gate electrodes of the TFTs. The gate lines 5 are covered with a first interlayer insulating layer 6 formed on the gate insulating layer 4. A plurality of data lines 7 each formed by an aluminum layer are formed on the first interlayer insulating layer 6. The data lines 7 extend in parallel to one another and in the column direction of the matrix of TFTs, and are laid out in such a way as to overlie the polycrystalline silicon layers 3 laid out in a matrix form as seen from a planar view. The source region 3a and the channel region 3b of each TFT are covered with the associated data line 7. The data lines 7 is electrically connected to the source region 3a of the matrix of TFTs via first contact holes 17 which penetrate the first interlayer insulating layer 6 and the gate insulating layer 4. The data lines 7 are covered with a second interlayer insulating layer 8 formed on the first interlayer insulating layer 6.

Wirings 9 are formed on the second interlayer insulating layer 8. Each wiring 9 has a double-layered structure and is formed by a first metal layer 9a of aluminum or an aluminum alloy and a second metal layer 9b of silver or a silver alloy patterned in the same pattern as that of the first metal layer 9a. The first metal layer 9a serves as the lower layer of the wiring 9, and the second metal layer 9b serves as the upper layer of the wiring 9. The wiring 9 is patterned so as to overlie the gate line 5 and the data line 7 of the associated TFT, and covers the TFT, and serves as a light-shielding layer. Each wiring 9 is electrically connected to the drain region 3c of the associated TFT via a second contact hole 18 which penetrates the second interlayer insulating layer 8, the first interlayer insulating layer 6 and the gate insulating layer 4. Each wiring is covered with a third interlayer insulating layer 10 formed on the second interlayer insulating layer 8.

A plurality of pixel electrodes 11 each having an approximately rectangular shape and formed by ITO are formed on the third interlayer insulating layer 10. The pixel electrodes 11 are respectively laid out at a plurality of pixel regions each surrounded by the associated gate line 5 and the associated data line 7. Each pixel electrode 11 is electrically connected to the associated wiring 9 via a third contact hole 19, which penetrates the third interlayer insulating layer 10. The pixel electrodes 11 are formed on the third interlayer insulating layer 10, and are covered with an alignment layer 12, which has undergone a predetermined alignment process.

An opposing substrate comprises a substrate 13 and an opposing electrode 14. The opposing electrode 14 of ITO is formed under the entire surface of the substrate 13, made of an insulative material, such as glass. An alignment layer 15, which has undergone a predetermined alignment process, is formed under the opposing electrode 14. A liquid crystal layer 16 is formed by sealing a liquid crystal between the TFT array substrate and the opposing substrate, both formed in the above-described manner, thereby yielding an active matrix type liquid crystal display.

In the active matrix type liquid crystal display, light is input from the surface side of the opposing substrate. The intensity of the light input to the pixel regions is adjusted by the liquid crystal layer 16, and the light then transmits the liquid crystal display. The light that is input to a non-transmittive region formed by the TFT, each gate line 5, each data line 7 and each wiring 9 is reflected by the second metal layer 9b of silver or a silver alloy of the wiring 9.

In general, while the reflectance of aluminum or an aluminum alloy is around 90%, the reflectance of silver or a silver alloy is 98% or higher. As the upper layer of the wiring 9 is formed by the second metal layer 9b of silver or a silver alloy, therefore, unnecessary incident light can be reflected efficiently, thus making it possible to reduce a rise in panel temperature.

Silver or a silver alloy, the material for the second metal layer 9b, also has an effect of a barrier metal which is needed to prevent inadequate contact between aluminum or an aluminum alloy and ITO of the pixel electrode, and aging-oriented degradation of the contact resistance. This makes it possible to acquire a highly reliable liquid crystal display without aging-oriented degradation of the contact resistance over a long period of time.

As each wiring 9 is formed by the lamination of the first metal layer 9a of aluminum or an aluminum alloy and the second metal layer 9b of silver or a silver alloy, it is possible to realize an active matrix type liquid crystal display which achieves a light reflectance performance and an electric corrosion preventing effect, equivalent to those obtained when the wiring 9 is entirely formed of silver or a silver alloy, at a lower cost.

The following will discuss a manufacture method for the liquid crystal display according to the first embodiment. First, the silicon oxide layer 2 is deposited on the entire top surface of the substrate 1 by ordinary chemical vapor deposition (CVD). Next, an amorphous silicon layer is deposited on the silicon oxide layer 2 using low pressure chemical vapor deposition (LPCVD) or plasma chemical vapor deposition (PCVD) or so, after which the amorphous silicon layer is crystallized by laser annealing or the like. The crystallized layer is then patterned by the ordinary photolithography technology and etching technology. As a result, a plurality of polycrystalline silicon layers 3, which serve as the active layers of the TFTs, are formed on the silicon oxide layer 2.

Next, the gate insulating layer 4 comprised of an silicon oxide layer is formed on the silicon oxide layer 2 by CVD, thereby covering the individual polycrystalline silicon layers 3 with the gate insulating layer 4. Then, an impurity-doped polycrystalline silicon layer or silicide layer is formed on the gate insulating layer 4, and is then patterned by the photolithography technology and etching technology, thus forming a plurality of gate lines 5. Subsequently, with each gate line 5 used as a mask, an impurity is selectively doped in each polycrystalline silicon layer 3 at a high concentration. As a result, the source region 3a and the drain region 3c are formed in each polycrystalline silicon layer 3, and a region between the source region 3a and the drain region 3c serves as the channel region 3b.

The first interlayer insulating layer 6 comprised of an silicon oxide layer is formed on the gate insulating layer 4 by CVD, so that each of the gate lines 5 is covered with the first interlayer insulating layer 6. Next, the first interlayer insulating layer 6 and the gate insulating layer 4 are selectively removed by the photolithography technology and etching technology, forming the first contact hole 17 through which the source region 3a is exposed. Subsequently, an aluminum alloy layer is formed on the first interlayer insulating layer 6 by sputtering or the like, and is patterned by the photolithography technology and etching technology, thereby forming a plurality of data lines 7. Each of the data lines 7 is also formed inside the first contact hole 17 to be electrically connected to the source region 3a. Then, the second interlayer insulating layer 8 comprised of an silicon oxide layer is formed on the first interlayer insulating layer 6 by CVD, so that each of the data lines 7 is covered with the second interlayer insulating layer 8. Next, the second interlayer insulating layer 8, the first interlayer insulating layer 6 and the gate insulating layer 4 are selectively removed by the photolithography technology and etching technology, forming the second contact hole 18 through which the drain region 3c is exposed.

Then, an aluminum alloy layer and a silver alloy layer of a silver-palladium-copper alloy are sequentially formed on the second interlayer insulating layer 8 by sputtering or the like. The thickness of the aluminum alloy layer or the first metal layer is 200 to 400 nm or so, for the thickness should be large enough not to cause light leakage by pin holes or so in order for the aluminum alloy layer to serve as a light-shielding layer. The thickness of the silver alloy layer or the second metal layer is 50 to 100 nm or so, for a certain thickness is needed to improve the light reflecting efficiency and prevent electric corrosion with ITO while the thickness of the silver alloy layer should be made smaller to reduce the amount of expensive silver to be used. The present inventors confirmed that the silver alloy layer with a thickness of about 50 nm could provide a stable light reflecting efficiency and a stable effect of preventing electric corrosion with ITO.

After the resist is patterned with the photolithography technology and etching technology, the aluminum alloy layer and the silver alloy layer are patterned by reactive ion etching (RIE) using a gas mixture of chlorine and argon or ion milling using an argon gas. As the aluminum alloy layer and the silver alloy layer are patterned by the same photolithography, the aluminum alloy layer and the silver alloy layer have the same shapes. As a result, the wirings 9 each comprised of the first metal layer 9a and the second metal layer 9b are formed. Each wiring 9 is also formed inside the second contact hole 18 to be electrically connected to the drain region 3c.

Next, the third interlayer insulating layer 10 of a silicon oxide is formed on the second interlayer insulating layer 8 by CVD, so that the wirings 9 are covered with the third interlayer insulating layer 10. Then, the third interlayer insulating layer 10 is selectively removed by the photolithography technology and etching technology, forming the third contact hole 19 through which the associated wiring 9 is exposed. Then, an ITO layer is formed on the third interlayer insulating layer 10, and is then patterned by the photolithography technology and etching technology, thus forming a plurality of pixel electrodes 11. Each pixel electrode 11 is also formed inside the third contact hole 19 to be electrically connected to the associated wiring 9. Next, the alignment layer 12 of polyimide is formed in such a way as to cover the pixel electrodes 11.

The opposing electrode 14 of ITO is formed on the entire surface of the opposing substrate 13. Then, the alignment layer 15 of polyimide is formed. The liquid crystal layer 16 is formed between the opposing substrate and the TFT array substrate, both formed in the above-described manner. Through the steps discussed above, the active matrix type liquid crystal display according to the first embodiment is acquired.

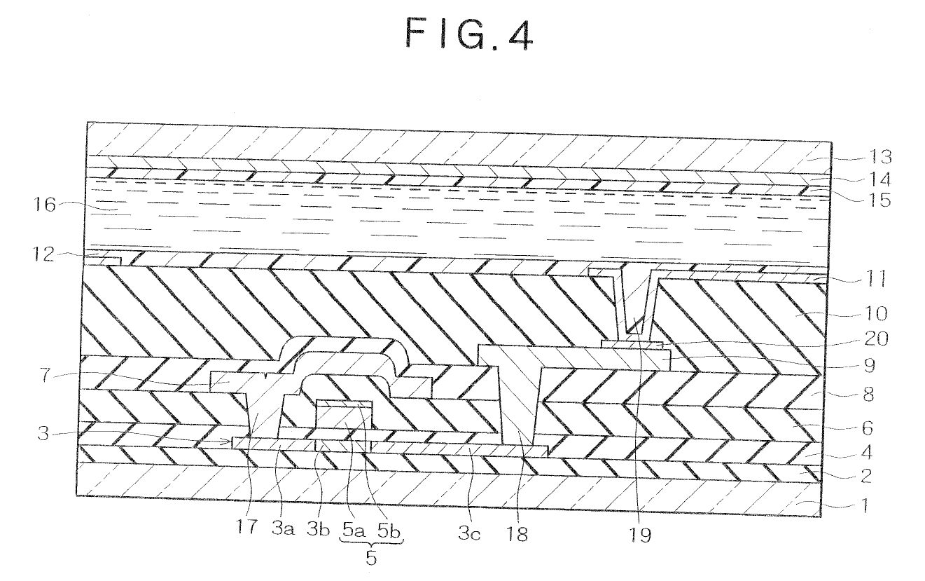

The second embodiments of the present invention will be described next. FIG. 4 is a cross-sectional view showing a liquid crystal display according to the second embodiment of the present invention, and the position of the cross section in FIG. 4 is equivalent to the position along line A-A in FIG. 1. Same reference symbols are given to those components in FIG. 4 which are the same as the corresponding components in FIG. 2 to avoid the redundant description of the components.

According to the embodiment, as shown in FIG. 4, the wiring 9 is not formed by the lamination of an aluminum alloy layer and a silver alloy layer unlike in the first embodiment, but is formed by a single layer of aluminum or an aluminum alloy as per the prior art, while each gate line 5 is formed by the lamination of an aluminum alloy layer and a silver alloy layer. Because the wiring 9 is formed by a single layer of aluminum or an aluminum alloy as per the prior art, which requires some measures against prevention of electric corrosion that would occur between the wiring 9 and the associated pixel electrode 11, the barrier metal 20 is intervened between the wiring 9 and the pixel electrode 11 as per the prior art shown in FIG. 2.

Even when the gate line 5 is formed by the lamination of an aluminum alloy layer and a silver alloy layer as per the embodiment, the light reflecting performance and the electric corrosion preventing effect equivalent to those obtained when the gate line 5 is formed of sliver alone are ensured. The thicknesses of the aluminum alloy and the silver alloy layer when the gate line 5 takes a double-layered structure are about the same as those when the wiring 9 takes a double-layered structure. Specifically, the thickness of the aluminum alloy layer which is the first metal layer is 200 to 400 nm or so, while the thickness of the silver alloy layer which is the second metal layer is 50 to 100 nm or so.

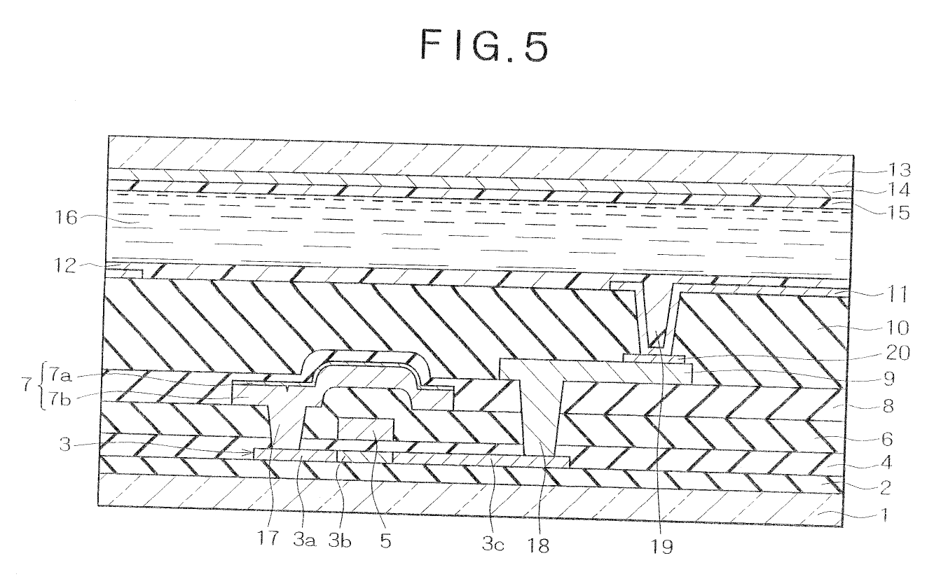

The third embodiments of the present invention will be described next. FIG. 5 is a cross-sectional view showing a liquid crystal display according to the third embodiment of the present invention, and the position of the cross section in FIG. 5 is equivalent to the position along line A-A in FIG. 1. Same reference symbols are given to those components in FIG. 5 which are the same as the corresponding components in FIG. 2 to avoid the redundant description of the components.

According to the embodiment, as shown in FIG. 5, the wiring 9 is not formed by the lamination of an aluminum alloy layer and a silver alloy layer unlike in the first embodiment, but is formed by a single layer of aluminum or an aluminum alloy as per the prior art, while each data line 7 is formed by the lamination of an aluminum alloy layer and a silver alloy layer. Because the wiring 9 is formed by a single layer of aluminum or an aluminum alloy as per the prior art, which requires some measures against prevention of electric corrosion that would occur between the wiring 9 and the associated pixel electrode 11, the barrier metal 20 is intervened between the wiring 9 and the pixel electrode 11 as per the prior art shown in FIG. 2.

Even when the data line 7 is formed by the lamination of an aluminum alloy layer and a silver alloy layer as per the embodiment, the light reflecting performance and the electric corrosion preventing effect equivalent to those obtained when the data line 7 is formed of sliver alone are ensured. The thicknesses of the aluminum alloy and the silver alloy layer when the data line 7 takes a double-layered structure are about the same as those when the wiring 9 takes a double-layered structure. Specifically, the thickness of the aluminum alloy layer which is the first metal layer is 200 to 400 nm or so, while the thickness of the silver alloy layer which is the second metal layer is 50 to 100 nm or so.

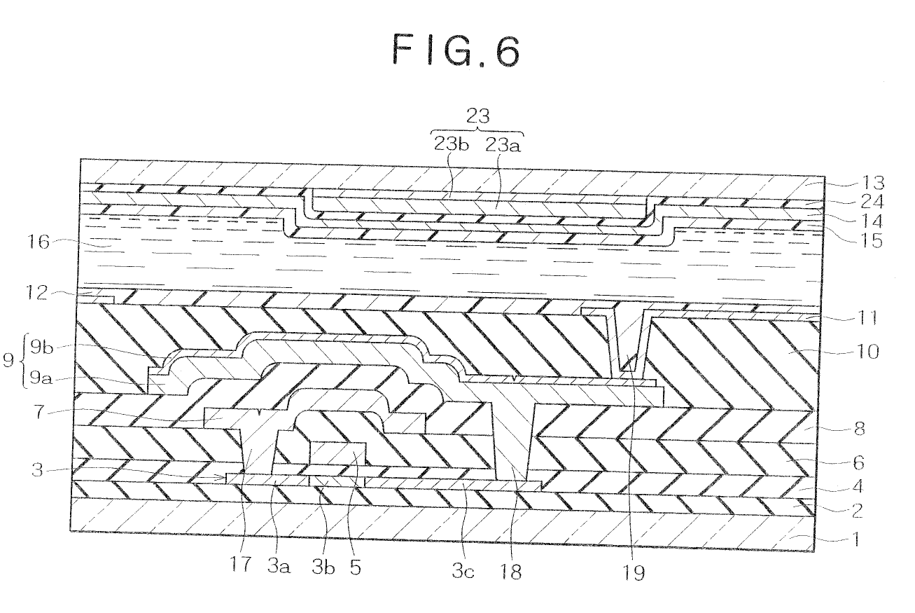

The fourth embodiments of the present invention will be described next. FIG. 6 is a cross-sectional view showing the schematic structure of a TFT array substrate which is the fourth embodiment of the present invention, and the position of the cross section in FIG. 6 is equivalent to the position along line A-A in FIG. 1. Same reference symbols are given to those components in FIG. 6 which are the same as the corresponding components in FIG. 2 to avoid the redundant description of the components.

An opposing light-shielding layer 23, which comprises a first metal opposing light-shielding layer 23a of aluminum or an aluminum alloy, and a second metal opposing light-shielding layer 23b of silver or a silver alloy, which is patterned in the same shape as the first metal opposing light-shielding layer 23a, is formed under a substrate 13 of the opposing substrate according to the embodiment, which is made of an insulative material such as glass. The substrate 13, the first metal opposing light-shielding layer 23a and the second metal opposing light-shielding layer 23b are laminated in the named order, and the opposing light-shielding layer 23 is patterned in a stripe shape in such a way as to overlie the individual gate lines 5 of the associated TFT array substrate as seen from a planar view, thereby ensuring an enhanced light shielding performance. The opposing light-shielding layer 23 may be patterned in such a way as to overlie the data lines 7 or overlie both the gate lines 5 and the data lines 7. A silicon oxide layer 24 and an opposing electrode 14 of ITO are formed entirely under the opposing light-shielding layer 23. An alignment layer 15, which has undergone a predetermined alignment process, is formed under the opposing electrode 14.

A liquid crystal layer 16 is formed by sealing a liquid crystal between the TFT array substrate and the opposing substrate, both formed in the above-described manner, thereby yielding an active matrix type liquid crystal display. In the active matrix type liquid crystal display, light is input from the surface side of the opposing substrate.

The intensity of the light input to the pixel regions is adjusted by the liquid crystal layer 16, and the light then transmits the liquid crystal display. The light that is input to a non-transmittive region formed by the TFT, each gate line 5, each data line 7 and each wiring 9 is reflected first by the second metal opposing light-shielding layer 23b of silver or a silver alloy formed on the light-incident side surface of the opposing light-shielding layer 23 formed on the opposing substrate side. Then, a part of the light that passes the non-shielded region and the opposing light-shielding layer 23 reaches the TFT array substrate. The light having reached the TFT array substrate is reflected by the second metal layer 9b of silver or a silver alloy formed on the light-incident side surface of the TFT array substrate. As the opposing light-shielding layer 23 is formed on the opposing substrate side, unnecessary incident light can be reflected more efficiently than is achieved by the first embodiment, thereby further reducing a rise in panel temperature.

According to the fourth embodiment, the opposing light-shielding layer 23 of the opposing substrate and each wiring 9 are each formed by the lamination of the first metal layer of aluminum or an aluminum alloy and the second metal layer of silver or a silver alloy. Therefore, the embodiment has an advantage of being able to provide a cheaper active matrix type liquid crystal display over the case where the opposing light-shielding layer 23 of the opposing substrate and the wirings 9 are all formed of silver or a silver alloy.

As the opposing light-shielding layer 23 formed on the opposing substrate is patterned in a stripe shape in such a way as to overlie the individual gate lines 5, alignment becomes easier as compared with the case where the light-shielding layer is formed in a lattice shape, thereby ensuring a lower manufacturing cost.

A manufacture method according to the fourth embodiment will now be described. The descriptions of those portions of the embodiment which are identical to the corresponding manufacturing processes will be omitted.

The opposing substrate 13 according to the fourth embodiment is made of an insulative material like glass. An aluminum alloy layer and a silver alloy layer of a sliver-palladium-copper alloy are formed in order on the substrate 13 by sputtering or the like. The thickness of the aluminum layer which is the first metal layer should be about 200 to 400 nm as per the first embodiment. The thickness of the silver alloy layer which is the second metal layer should be about 50 to 100 nm. Subsequently, the aluminum alloy layer and the silver alloy layer are patterned in a stripe shape by the photolithography technology. The pattern extends in the row direction of the associated TFTs laid out in a matrix form and approximately covers the gate lines. Next, the aluminum alloy layer and the silver alloy layer are patterned in the same shape by RIE using a gas mixture of chlorine and argon or ion milling using an argon gas. This yields the opposing light-shielding layer 23 comprising the first metal opposing light-shielding layer 23a and the second metal opposing light-shielding layer 23b. Then, the silicon oxide layer 24 and the opposing electrode 14 of ITO are formed on the entire surface of the opposing light-shielding layer 23 by sputtering or CVD or the like. Then, the alignment layer 5 of polyimide is formed. A liquid crystal is sealed between the opposing substrate and the TFT array substrate, constituted in the above-described manner, thereby forming the liquid crystal layer 16. Through the steps, the active matrix type liquid crystal display according to the fourth embodiment is provided.

As the opposing light-shielding layer 23 is patterned in a stripe shape, the alignment of the opposing substrate with the TFT array substrate should be made accurately only in the row direction of the TFTs laid out in a matrix form, as compared with the case where the opposing light-shielding layer is patterned in a lattice shape. This makes the bonding step easier. What is more, the reflection efficiency is improved as compared with the first embodiment where no opposing light-shielding layer is formed on the opposing substrate.

As the embodiment employs the step of forming each wiring 9 by the lamination of the a first metal layer 9a of an aluminum alloy and the second metal layer 9b of a silver alloy, the advantage of the TFT array substrate discussed in the foregoing description of the first embodiment is acquired as well. That is, it is possible to acquire an active matrix type liquid crystal display which achieves the light reflecting performance and the electric corrosion preventing effect, equivalent to those obtained when only silver is used for the wirings 9, at a lower cost.

Although the opposing light-shielding layer 23 is patterned in a stripe shape in such a way as to overlie the individual gate lines 5 of the associated TFT array substrate, thereby contributing to enhancing the light shielding performance, in the fourth embodiment, patterning the opposing light-shielding layer 23 in a stripe shape in such a way as to overlie the data lines 7 of the TFT array substrate can likewise contribute to enhancing the light shielding performance.

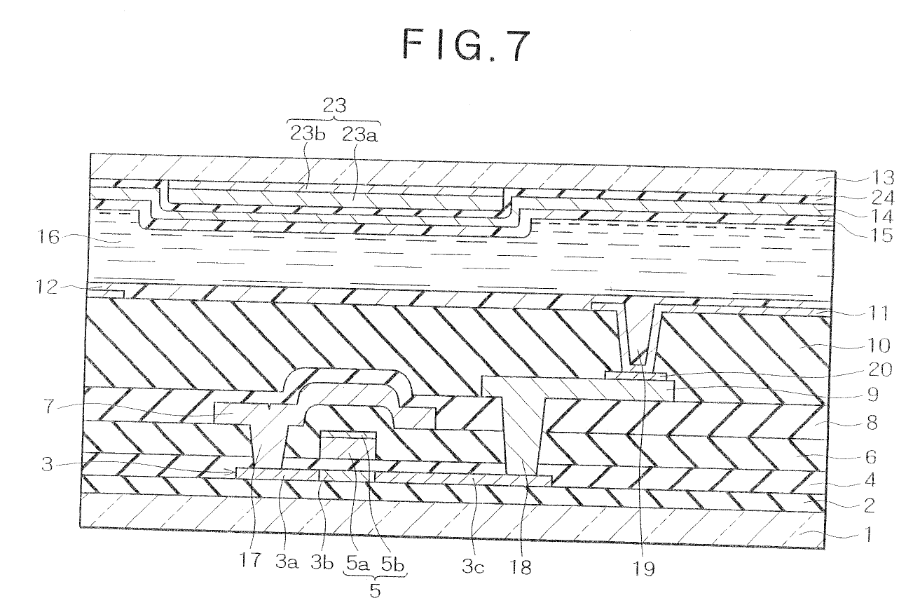

The fifth embodiments of the present invention will be described next. FIG. 7 is a cross-sectional view showing a liquid crystal display according to the fifth embodiment of the present invention, and the position of the cross section in FIG. 7 is equivalent to the position along line A-A in FIG. 1. Same reference symbols are given to those components in FIG. 7 which are the same as the corresponding components in FIG. 2 to avoid the redundant description of the components.

As shown in FIG. 7, the embodiment is the combination of the second embodiment and the fourth embodiment, where the wiring 9 is not formed by the lamination of an aluminum alloy layer and a silver alloy layer unlike in the first embodiment, but is formed by a single layer of aluminum or an aluminum alloy as per the prior art, while each gate line 5 is formed by the lamination of an aluminum alloy layer and a silver alloy layer. Because the wiring 9 is formed by a single layer of aluminum or an aluminum alloy as per the prior art, which requires some measures against prevention of electric corrosion that would occur between the wiring 9 and the associated pixel electrode 11, the barrier metal 20 is intervened between the wiring 9 and the pixel electrode 11 as per the prior art shown in FIG. 2.

Even when the gate line 5 is formed by the lamination of an aluminum alloy layer and a silver alloy layer as per the embodiment, the light reflecting performance and the electric corrosion preventing effect equivalent to those obtained when the gate line 5 is formed of sliver alone are ensured. The thicknesses of the aluminum alloy and the silver alloy layer when the gate line 5 takes a double-layered structure are about the same as those when the wiring 9 takes a double-layered structure. Specifically, the thickness of the aluminum alloy layer which is the first metal layer should be 200 to 400 nm or so, while the thickness of the silver alloy layer which is the second metal layer should be 50 to 100 nm or so.

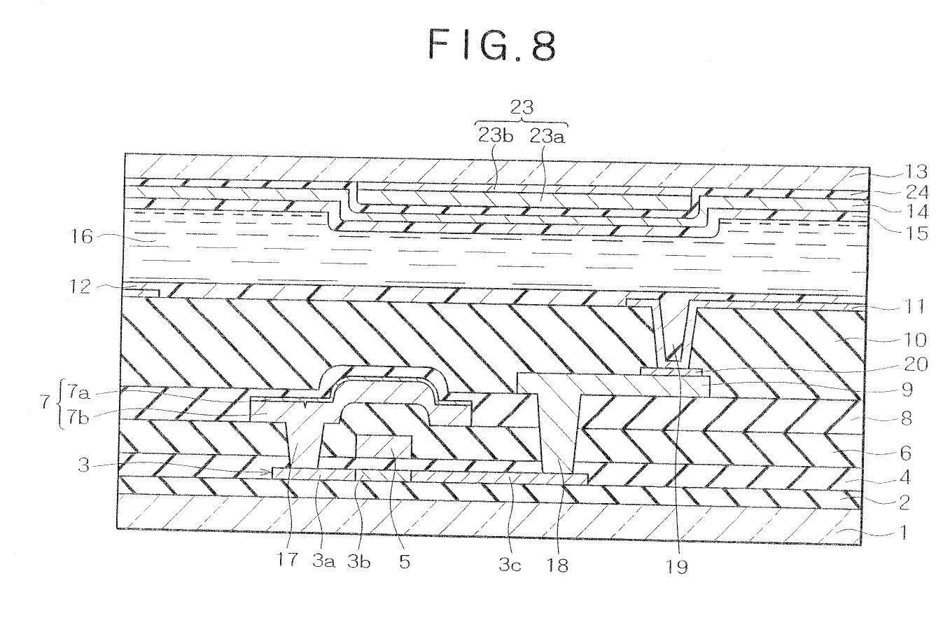

The sixth embodiments of the present invention will be described next. FIG. 8 is a cross-sectional view showing a liquid crystal display according to the sixth embodiment of the present invention, and the position of the cross section in FIG. 8 is equivalent to the position along line A-A in FIG. 1. Same reference symbols are given to those components in FIG. 8 which are the same as the corresponding components in FIG. 2 to avoid the redundant description of the components.

As shown in FIG. 8, the embodiment is the combination of the third embodiment and the fourth embodiment, where the wiring 9 is not formed by the lamination of an aluminum alloy layer and a silver alloy layer unlike in the first embodiment, but is formed by a single layer of aluminum or an aluminum alloy as per the prior art, while each data line 7 is formed by the lamination of an aluminum alloy layer and a silver alloy layer. Because the wiring 9 is formed by a single layer of aluminum or an aluminum alloy as per the prior art, which requires some measures against prevention of electric corrosion that would occur between the wiring 9 and the associated pixel electrode 11, the barrier metal 20 is intervened between the wiring 9 and the pixel electrode 11 as per the prior art shown in FIG. 2.

Even when the data line 7 is formed by the lamination of an aluminum alloy layer and a silver alloy layer as per the embodiment, the light reflecting performance and the electric corrosion preventing effect equivalent to those obtained when the data line 7 is formed of sliver alone are ensured. The thicknesses of the aluminum alloy and the silver alloy layer when the data line 7 takes a double-layered structure are about the same as those when the wiring 9 takes a double-layered structure. Specifically, the thickness of the aluminum alloy layer which is the first metal layer should be 200 to 400 nm or so, while the thickness of the silver alloy layer which is the second metal layer should be 50 to 100 nm or so.

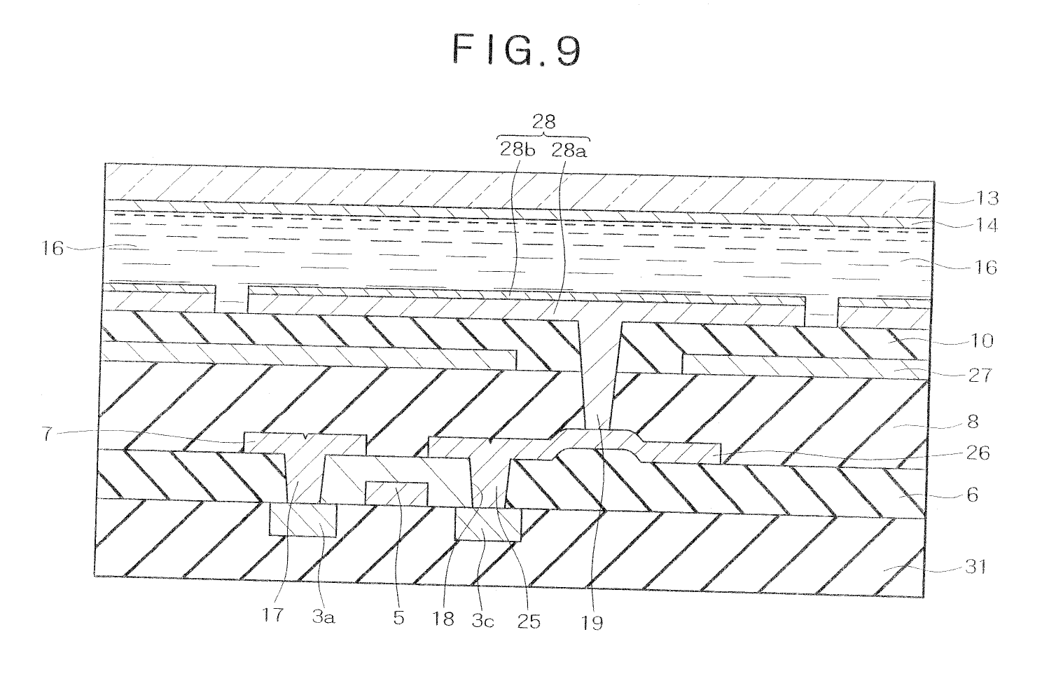

The seventh embodiments of the present invention will be described next. FIG. 9 is a cross-sectional view showing a liquid crystal display according to the seventh embodiment of the present invention, which is a reflection type liquid crystal display.

As shown in FIG. 9, the liquid crystal display according to the embodiment has an MOS array substrate and an opposing substrate arranged opposite to each other and in parallel to each other, and a liquid crystal layer formed by filling a liquid crystal between the MOS array substrate and the opposing substrate. The MOS array substrate has a silicon substrate 31. Formed on the silicon substrate 31 are a matrix of MOS transistors each comprised of a source region 3a, a drain region 3c and a gate line 5 formed of impurity-doped polysilicon or so.

The gate lines 5 are covered with a first interlayer insulating layer 6. The gate lines 5 extend in parallel to one another in the row direction. Each gate line 5 serves as the gate electrode of the associated one of the MOS transistors laid out in a matrix form. A plurality of data lines 7 and a plurality of drain electrodes 25, formed by an aluminum layer or the like, are formed on the first interlayer insulating layer 6. The data lines 7 extend in parallel to one another in the column direction of the matrix of MOS transistors, and are electrically connected to the source regions 3a of the associated MOS transistors laid out in a matrix form via first contact holes 17 which penetrate the first interlayer insulating layer 6. Each drain electrode 25 is connected to the drain region 3c via a second contact hole 18 formed in the first interlayer insulating layer 6. The data lines 7 and the drain electrodes 25 are covered with a second interlayer insulating layer 8.

A light-shielding layer 27 of a metal or silicide or so is formed on the second interlayer insulating layer 8, and is covered with a third interlayer insulating layer 10. A photolithography technology reflection pixel electrodes 28 each comprising a first metal layer 28a of aluminum or an aluminum alloy and a second metal layer 28b of silver or a silver alloy patterned in the same shape as the first metal layer 28a are formed on the third interlayer insulating layer 10. Each reflection pixel electrode 28 is electrically connected to the drain region 3c of the associated MOS transistor via a third contact hole 19, which penetrates the third interlayer insulating layer 10 and the second interlayer insulating layer 8. A storage capacitor 26 is formed between each drain electrode 25 and the light-shielding layer 27.

The opposing substrate has an opposing electrode 14 of ITO formed under the entire surface of a substrate 13, made of an insulative material like glass. A liquid crystal layer 16 is formed by sealing a liquid crystal between the MOS array substrate and the opposing substrate, both formed in the above-described manner, thereby yielding an active matrix type liquid crystal display.

In the active matrix type liquid crystal display with the above-described structure, light is input from the surface side of the opposing substrate. The reflection pixel electrode 28 has a capability of reflecting light input from the opposing substrate, and the capability of functioning as a display electrode when a voltage is applied to the liquid crystal layer 16 from the MOS transistor. The light that is input from the opposing substrate is reflected by the second metal layer 28b of silver or a silver alloy formed on that side of the reflection pixel electrode 28 which is closest to the light incident side.

As mentioned earlier, while the reflectance of aluminum or an aluminum alloy is around 90%, the reflectance of silver or a silver alloy is 98% or higher. As a metal layer of silver or a silver alloy is formed on that side of the MOS array substrate which is closest to the light incident side, therefore, unnecessary incident light can be reflected efficiently, thus making it possible to reduce a rise in panel temperature.

The formation of each reflection pixel electrode 28 is formed by the lamination of the first metal layer 28a of aluminum or an aluminum alloy and the second metal layer 28b of silver or a silver alloy has an advantage such that a cheaper active matrix type liquid crystal display can be provided as compared with the case where the reflection pixel electrode 28 is entirely formed of silver or a silver alloy.

A manufacture method for the liquid crystal display according to the seventh embodiment will be described referring to FIG. 9. First, a high-concentration impurity is selectively doped into regions on the silicon substrate 31 which correspond to the source region 3a and the drain region 3c.

Next, the gate lines 5 of impurity-doped polysilicon are formed. Then, the first interlayer insulating layer 6 of a silicon oxide is formed on the silicon substrate 31 by CVD, so that the source regions 3a, the drain regions 3c and the gate lines 5 are covered with the first interlayer insulating layer 6. Subsequently, the first interlayer insulating layer 6 is selectively removed to form the first contact hole 17 and the second contact hole 18 through which the source region 3a and the drain region 3c are respectively exposed. Then, an aluminum alloy layer is formed on the first interlayer insulating layer 6 by sputtering or the like, and is patterned to form the data lines 7 and the drain electrodes 25. Each of the data lines 7 is also formed inside the first contact hole 17 to be electrically connected to the source region 3a. Likewise, each drain electrode 25 is electrically connected to the drain region 3c via the second contact hole 18.

Next, the second interlayer insulating layer 8 of a silicon oxide is formed on the data lines 7 and the drain electrodes 25 by CVD, followed by the formation of the light-shielding layer 27 of chromium. The light-shielding layer 27 is so patterned as to approximately cover the MOS transistors. Next, the third interlayer insulating layer 10 of a silicon oxide is formed on the light-shielding layer 27, then the third interlayer insulating layer 10 and the second interlayer insulating layer 8 are selectively removed by the photolithography technology and etching technology, forming the third contact hole 19 through which the associated drain electrode 25 is exposed.

Subsequently, an aluminum alloy layer and a silver alloy layer of a sliver-palladium-copper alloy are formed on the third interlayer insulating layer 10 in order by sputtering or so. The aluminum alloy layer and the silver alloy layer can be patterned by RIE using a gas mixture of chlorine and argon or ion milling using an argon gas after the resist is patterned by the photolithography technology. As the aluminum alloy layer and the silver alloy layer are patterned by the same photolithography, the aluminum alloy layer and the silver alloy layer have the same shapes. As a result, the reflection pixel electrodes 28 each comprised of the first metal layer 28a and the second metal layer 28b are formed. Each reflection pixel electrode 28 is also formed inside the third contact hole 19 to be electrically connected to the drain region 3c.

The opposing electrode 14 of ITO is formed on the entire surface of the opposing substrate 13. Then, a liquid crystal is sealed between the opposing substrate and the MOS array substrate, both formed in the above-described manner. thereby forming the liquid crystal layer 16. Through the steps discussed above, the active matrix type liquid crystal display according to the seventh embodiment is acquired.

As described above, the active matrix type liquid crystal display according to the seventh embodiment employs the step of forming the reflection pixel electrode 28 by the lamination of the first metal layer 28a of aluminum alloy and the high-reflectance second metal layer 28b of a silver alloy formed on the light incident side.

Because an inexpensive aluminum alloy to be used as one of the materials for an ordinary semiconductor device is used for the first metal layer 28a and a silver alloy is used only for the second metal layer 28b on the light incident side, this manufacture method can provide a cheaper active matrix type liquid crystal display as compared with the manufacture method which forms the reflection pixel electrode 28 entirely of expensive silver.

In addition, the use of a silver alloy for the second metal layer 28b located closest to the light incident side can ensure a higher reflectance an aluminum alloy layer or less light absorption, thus making it possible to suppress a rise in panel temperature. Accordingly, a highly reliable active matrix type liquid crystal display can be provided.

What is claimed is:

1. An active matrix type liquid crystal display comprising:
an array substrate having
a substrate,
a plurality of transistors laid out on said substrate in a matrix form,
gate lines extending along a row direction of that matrix, and each having a first metal layer of aluminum or an aluminum alloy and a second metal layer of silver or a silver alloy laminated on a light-incident side surface of said first metal layer,
data lines extending along a column direction of said matrix and connected to one of source regions and drain regions of said transistors, pixel electrodes arranged at pixel regions on said substrate,
wirings for respectively connecting the other one of said source regions and said drain regions of said transistors to said pixel electrodes, and a barrier metal intervening between each of said pixel electrodes and an associated one of said wirings;
an opposing substrate arranged opposite to said array substrate; and
a liquid crystal layer provided between said array substrate and said opposing substrate.

2. An active matrix type liquid crystal display comprising:
an array substrate having
a substrate,
a plurality of transistors laid out on said substrate in a matrix form,
gate lines extending along a row direction of that matrix,
data lines extending along a column direction of said matrix and connected to one of source regions and drain regions of said transistors, each of said data lines having a first metal layer of aluminum or an aluminum alloy and a second metal layer of silver or a silver alloy laminated on a light-incident side surface of said first metal layer,
pixel electrodes arranged at pixel regions on said substrate,
wirings for respectively connecting the other one of said source regions and said drain regions of said transistors to said pixel electrodes, and
a barrier metal intervening between each of said pixel electrodes and an associated one of said wirings;
an opposing substrate arranged opposite to said array substrate; and
a liquid crystal layer provided between said array substrate and said opposing substrate.

3. An active matrix type liquid crystal display comprising:
an array substrate having
a substrate,
a plurality of transistors laid out on said substrate in a matrix form,
gate lines extending along a row direction of that matrix,
data lines extending along a column direction of said matrix and connected to one of source regions and drain regions of said transistors, pixel electrodes arranged at pixel regions on said substrate, and
wirings for respectively connecting the other one of said source regions and said drain regions of said transistors to said pixel electrodes;
an opposing substrate arranged opposite to said array substrate and having
a substrate, and
an opposing light-shielding layer laid out at a region including a region directly overlying at least one of said gate lines and said data lines on said substrate, said opposing light-shielding layer having a first metal layer of aluminum or an aluminum alloy and a second metal layer of silver or a silver alloy laminated on a light-incident side surface of said first metal layer; and
a liquid crystal layer provided between said array substrate and said opposing substrate.

4. The active matrix type liquid crystal display according to claim 3, wherein each of said wirings has:
a first metal layer of aluminum or an aluminum alloy; and
a second metal layer of silver or a silver alloy laminated on a light-incident side surface of said first metal layer.

5. The active matrix type liquid crystal display according to claim 3, wherein each of said gate lines has:
a first metal layer of aluminum or an aluminum alloy; and
a second metal layer of silver or a silver alloy laminated on a light-incident side surface of said first metal layer.

6. The active matrix type liquid crystal display according to claim 3, wherein each of said data lines has:
a first metal layer of aluminum or an aluminum alloy;
and
a second metal layer of silver or a silver alloy laminated on a light-incident side surface of said first metal layer.

7. An active matrix type liquid crystal display comprising:
an array substrate having
a semiconductor substrate,
a plurality of transistors laid out at a top surface of said semiconductor substrate in a matrix form,
gate lines extending along a row direction of that matrix,
data lines extending along a column direction of said matrix and connected to one of source regions and drain regions of said transistors, and
reflection pixel electrodes which reflect light and are connected to the other one of said source regions and said drain regions of said transistors,
each of said reflection pixel electrodes having a first metal layer of aluminum or an aluminum alloy and a second metal layer of silver or a silver alloy laminated on a light-incident side surface of said first metal layer;
an opposing substrate arranged opposite to said array substrate; and
a liquid crystal layer provided between said array
substrate and said opposing substrate.

8. A manufacture method for an active matrix type liquid crystal display comprising the steps of:
forming an array substrate, said forming of said array substrate including the steps of
forming a plurality of transistors on said substrate in a matrix form,
forming gate lines in such a way as to extend along a row direction of that matrix,
forming data lines in such a way as to extend along a column direction of said matrix and connected to one of source regions and drain regions of said transistors, and
forming wirings in such a way that said wirings are respectively connected to the other one of said source regions and said drain regions of said transistors, said forming of said wiring comprising the steps of forming a first metal layer of aluminum or an aluminum alloy, forming a second metal layer of silver or a silver alloy laminated on a light-incident side surface of said first metal layer, and patterning said first metal layer and said second metal layer by etching said first metal layer and said second metal layer using a same resist pattern, and
forming pixel electrodes at pixel regions on said substrate in such a way as to be connected to said wirings;
forming an opposing substrate; and
forming a liquid crystal layer between said array substrate and said opposing substrate, after arranging said array substrate and said opposing substrate opposite to each other.

9. A manufacture method for an active matrix type liquid crystal display comprising the steps of:
forming an array substrate, said forming of said array substrate including the steps of
forming a plurality of transistors on said substrate in a matrix form,
forming gate lines in such a way as to extend along a row direction of that matrix,
forming data lines in such a way as to extend along a column direction of said matrix and connected to one of source regions and drain regions of said transistors,
forming wirings in such a way that said wirings are respectively connected to the other one of said source regions and said drain regions of said transistors,
forming a barrier metal on a part of said wirings, and
forming pixel electrodes at pixel regions on said substrate in such a way as to be connected to said wirings via said barrier metal;
forming an opposing substrate, said forming of said opposing substrate having the step of forming an opposing light-shielding layer at a region including a region directly overlying at least one of said gate lines and said data lines on said substrate, said forming of said opposing light-shielding layer comprising the steps of
forming a first metal layer of aluminum or an aluminum alloy,
forming a second metal layer of silver or a silver alloy laminated on a light-incident side surface of said first metal layer, and
patterning said first metal layer and said second metal layer by etching said first metal layer and said second metal layer using a same resist pattern; and
forming a liquid crystal layer between said array substrate and said opposing substrate, after arranging said array substrate and said opposing substrate opposite to each other.

10. A manufacture method for an active matrix type liquid crystal display comprising the steps of:
forming an array substrate, said forming of said array substrate including the steps of
forming a plurality of transistors on a semiconductor substrate in a matrix form,
forming gate lines in such a way as to extend along a row direction of that matrix,
forming data lines in such a way as to extend along a column direction of said matrix and connected to one of source regions and drain regions of said transistors, and
forming reflection pixel electrodes, which reflect light, in such a way that said reflection pixel electrodes are respectively connected to the other one of said source regions and said drain regions of said transistors, said forming of said reflection pixel electrode comprising the step of forming a first metal layer of aluminum or an aluminum alloy, forming a second metal layer of silver or a silver alloy laminated on a light-incident side surface of said first metal layer, and patterning said first metal layer and said second metal layer by etching said first metal layer and said second metal layer using a same resist pattern;
forming an opposing substrate; and
arranging said array substrate and said opposing substrate opposite to each other, and forming a liquid crystal layer between said array substrate and said opposing substrate.

11. The active matrix type liquid crystal display according to claim 1, wherein the first metal layer has a thickness of 200 to 400 nm, and the second metal layer has a thickness of 50 to 100 nm.

12. The active matrix type liquid crystal display according to claim 2, wherein the first metal layer has a thickness of 200 to 400 nm, and the second metal layer has a thickness of 50 to 100 nm.

13. The active matrix type liquid crystal display according to claim 3, wherein the first metal layer has a thickness of 200 to 400 nm, and the second metal layer has a thickness of 50 to 100 nm.

14. The active matrix type liquid crystal display according to claim 7, wherein the first metal layer has a thickness of 200 to 400 nm, and the second metal layer has a thickness of 50 to 100 nm.

15. The active matrix type liquid crystal display according to claim 1, wherein the first metal layer has a reflectance of about 90%, and the second metal layer has a reflectance of 98% or higher.

16. The active matrix type liquid crystal display according to claim 2, wherein the first metal layer has a reflectance of about 90%, and the second metal layer has a reflectance of 98% or higher.

17. The active matrix type liquid crystal display according to claim 3, wherein the first metal layer has a reflectance of about 90%, and the second metal layer has a reflectance of 98% or higher.

18. The active matrix type liquid crystal display according to claim 7, wherein the first metal layer has a reflectance of about 90%, and the second metal layer has a reflectance of 98% or higher.
